(19) United States
(12) Patent Application Publication
(10) Pub. No.: US 2025/0299968 A1
(43) Pub. Date: Sep. 25, 2025

(54) SEMICONDUCTOR PROCESSING TOOL AND METHODS OF OPERATION

(71) Applicant: Taiwan Semiconductor Manufacturing Company, Ltd., Hsinchu (TW)

(72) Inventors: Yi-Cheng LIN, New Taipei City (TW); Peng-Chung JANGJIAN, Hsinchu (TW)

(21) Appl. No.: 18/615,579

(22) Filed: Mar. 25, 2024

(51) Int. Cl. H01L 21/321; H01L 21/306; H01L 21/67

(52) U.S. Cl. CPC H01L 21/3212; H01L 21/30625; H01L 21/67023; H01L 21/67092

(57) ABSTRACT

Some implementations described herein provide a planarization tool and methods of operation. The planarization tool includes a closed-loop heating system with two heating sources to control a temperature of a slurry mixture on a polishing pad as part of a planarization operation. The two heating sources include an electro-thermal system that heats slurry in a slurry line of the planarization tool and a nozzle that emits a heated fluid near a dispense point of the slurry. The closed-loop heating system with the two heating sources further includes a temperature sensor that provides feedback related to a temperature of a mixture of slurry on the polishing pad during the planarization operation.

### BACKGROUND

A layer, a substrate, or a semiconductor wafer may be planarized using a polishing or planarizing technique such as chemical mechanical polishing/planarization (CMP). A CMP operation may include depositing a slurry (or polishing compound) onto a polishing pad. A semiconductor wafer may be mounted to and secured by a carrier, which may rotate the semiconductor wafer as the semiconductor wafer is pressed against the polishing pad. The slurry and polishing pad act as an abrasive that polishes or planarizes one or more layers (e.g., metallization layers) of the semiconductor wafer as the semiconductor wafer is rotated. The polishing pad may also be rotated to ensure a continuous supply of slurry is applied to the polishing pad.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example planarization tool described herein.

FIGS. 2A-2C are diagrams of example implementations of a processing chamber of the planarization tool described herein.

FIGS. 3A-3D are diagrams of an example implementation of a planarization tool described herein.

FIGS. 4A and 4B are diagrams of example performance data described herein.

FIG. 5 is a diagram of example components of a device described herein.

FIGS. 6 and 7 are flowcharts of example processes described herein.

FIG. 8 is a diagram of an example implementation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A planarization tool, such as a chemical mechanical polishing/planarization (CMP) tool, may include a heating system that heats a slurry used in a planarization operation performed upon a semiconductor wafer. Heating the slurry may improve the planarization operation by increasing chemical reaction rates, reducing a viscosity of the slurry, and/or improving suspension of abrasive particles that may be included in the slurry. Relative to a polishing/planarization operation using an unheated slurry, the polishing/planarization operation using the heated slurry may yield a semiconductor wafer having an improved flatness and/or smoothness.

In some cases, the heating system is an open-loop heating system with a single heating source that emits superheated steam from a nozzle near a dispense point of the slurry onto the semiconductor wafer. In such cases, the use of the superheated steam may require an undue amount to time for the slurry to reach a target temperature, leading to inefficient utilization of the planarization tool and/or wasted use of the slurry. Additionally, the superheated steam may have instabilities that cause large variations in a temperature of the slurry, leading to variations in a flatness of the semiconductor wafer to decrease a yield of semiconductor devices from the semiconductor wafer.

Some implementations described herein provide a planarization tool and methods of operation. The planarization tool includes a closed-loop heating system with two heating sources to control a temperature of a slurry mixture on a polishing pad in a planarization operation. The two heating sources include an electro-thermal system that heats slurry in a slurry line of the planarization tool and a nozzle that emits a heated fluid near a dispense point of the slurry. The closed-loop heating system with the two heating sources further includes a temperature sensor that provides feedback related to a temperature of a mixture of slurry on the polishing pad during the polishing/planarization operation.

Relative to an open-loop heating system with a single heating source, the closed-loop heating system with two heating sources increases a rate at which a temperature of the slurry is increased to improve a utilization of the planarization tool and/or reduce a waste of the slurry. Additionally, and relative to the open-loop heating system with the single heating source, the closed-loop heating system with the two heating sources improves a control of a temperature of the slurry to reduce variations in a flatness of the semiconductor wafer and improve a yield of semiconductor devices from the semiconductor wafer.

In this way, a utilization of the planarization tool is improved, an amount of wasted slurry is reduced, and/or a yield of semiconductor devices from the semiconductor wafer is increased. Furthermore, an amount of resources used to fabricate a volume of the semiconductor devices (e.g., semiconductor processing tools, labor, raw materials, and/or computing resources) is reduced.

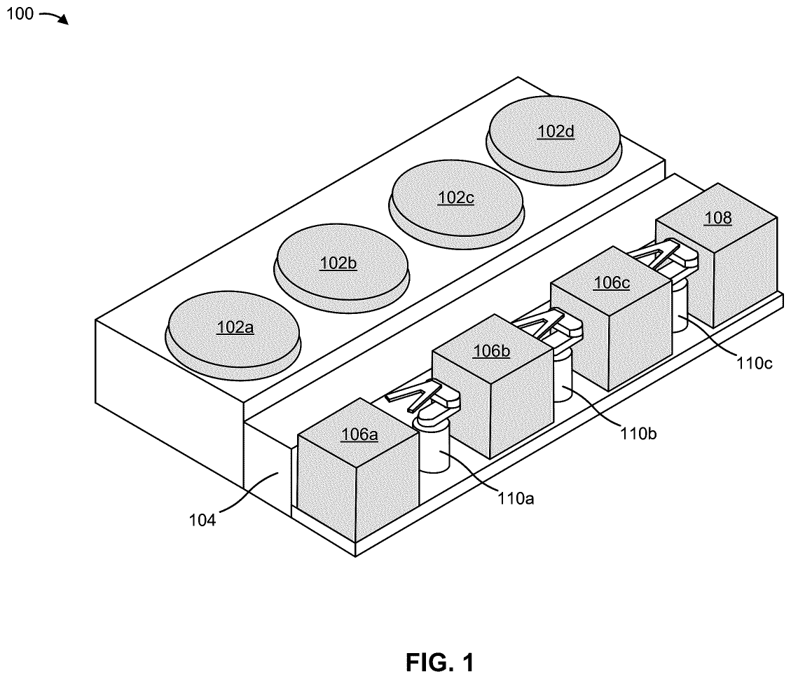

FIG. 1 is a diagram of an example planarization tool 100 described herein. The planarization tool 100 includes a CMP tool or another type of semiconductor processing tool that is capable of polishing or planarizing a semiconductor wafer, a semiconductor device, and/or another type of semiconductor substrate. The planarization tool 100 includes one or more processing chambers 102a-102d in which layers and/or structures of a semiconductor wafer are polished or planarized. In some implementations, a processing chamber 102 is configured to polish or planarize a surface (or a layer or structure) of a semiconductor wafer with a combination of chemical and mechanical forces (e.g., chemical etching and free abrasive polishing). The planarization tool 100 is configured to utilize an abrasive and corrosive chemical slurry in conjunction with a polishing pad and retaining ring (e.g., typically of a greater diameter than the semiconductor wafer) in a processing chamber 102. To perform a planarization operation (also referred to herein as a CMP operation), the planarization tool 100 presses the polishing pad against the semiconductor wafer in the processing chamber 102 using a dynamic polishing head that is held in place by the retaining ring. The dynamic polishing head may rotate with different axes of rotation to remove material and even out any irregular topography of a layer or a structure of the semiconductor wafer, thereby making the layer or a structure of the semiconductor wafer flat or planar.

The planarization tool 100 includes a transfer chamber 104 in which semiconductor wafers are transferred to and from the processing chamber(s) 102. Moreover, semiconductor wafers are transferred between the transfer chamber 104 and one or more cleaning chambers 106a-106c included in the planarization tool 100. A cleaning chamber (also referred to as a CMP cleaning chamber or a post-CMP cleaning chamber) is a component of the planarization tool 100 that is configured to perform a post-CMP cleaning operation to clean or remove residual slurry and/or removed material from a semiconductor wafer that has undergone a CMP operation. In some implementations, the planarization tool 100 includes a plurality of cleaning chambers 106, and the planarization tool 100 is configured to process a semiconductor wafer through a plurality of sequential post-CMP cleaning operations in the plurality of cleaning chambers 106. As an example, the planarization tool 100 may process a semiconductor wafer in a first post-CMP cleaning operation in a cleaning chamber 106a, may process the semiconductor wafer in a second post-CMP cleaning operation in a cleaning chamber 106b, may process the semiconductor wafer in a third post-CMP cleaning operation in a cleaning chamber 106c, and so on.

A cleaning chamber 106 cleans a semiconductor wafer using a cleaning agent such as isopropyl alcohol (IPA), a chemical solution that includes a plurality of cleaning chemicals, and/or another type of cleaning agent. The planarization tool 100 includes one or more types of cleaning chambers 106. Each type of cleaning chamber 106 is configured to clean a semiconductor wafer using a different type of cleaning device. In some implementations, a cleaning chamber 106 includes a brush-type cleaning chamber. A brush-type cleaning chamber is a cleaning chamber that includes one or more cleaning brushes (or roller brushes) that are configured to spin or rotate to brush-clean a semiconductor wafer. In some implementations, a cleaning chamber 106 includes a pen-type cleaning chamber. A pen-type cleaning chamber is a cleaning chamber that includes a cleaning pen (or cleaning pencil) that is configured to provide fine-tuned and detailed cleaning of a semiconductor substrate.

In some implementations, the cleaning chambers 106 of the planarization tool 100 are arranged such that a semiconductor wafer is first processed in one or more brush-type cleaning chambers (e.g., to remove a large amount of removed material and residual slurry from the semiconductor wafer), and is then processed in a pen-type cleaning chamber (e.g., to provide detailed cleaning of structures and/or recesses in the semiconductor wafer). As an example, the cleaning chambers 106a and 106b may be configured as brush-type cleaning chambers, and cleaning chamber 106c may be configured as a pen-type cleaning chamber.

The planarization tool 100 includes a rinsing chamber 108 that is configured to rinse a semiconductor wafer after one or more post-CMP cleaning operations. The rinsing chamber 108 rinses a semiconductor wafer to remove residual cleaning agent from the semiconductor wafer. The rinsing chamber 108 is configured to use a rinsing agent, such as deionized water (DIW) or another type of rinsing agent, to rinse a semiconductor wafer. Semiconductor wafers are transferred to the rinsing chamber 108 from a cleaning chamber 106 directly or through the transfer chamber 104. In some implementations, a semiconductor wafer is processed in a drying operation in the rinsing chamber 108, in which the semiconductor wafer is dried to prevent oxidation and/or other types of contamination of the semiconductor wafer.

The planarization tool 100 includes a plurality of transport devices 110a-110c. The transport devices include robot arms or other types of transport devices that are configured to transfer semiconductor wafers between the processing chamber(s) 102, the transfer chamber 104, the cleaning chamber(s) 106, and/or the rinsing chamber 108.

Furthermore, while described in the context of the planarization tool 100 performing a planarization operation herein, this description equally applies to the planarization tool 100 performing a polishing operation.

As indicated above, FIG. 1 is provided as an example. Other examples may differ from what is described with regard to FIG. 1.

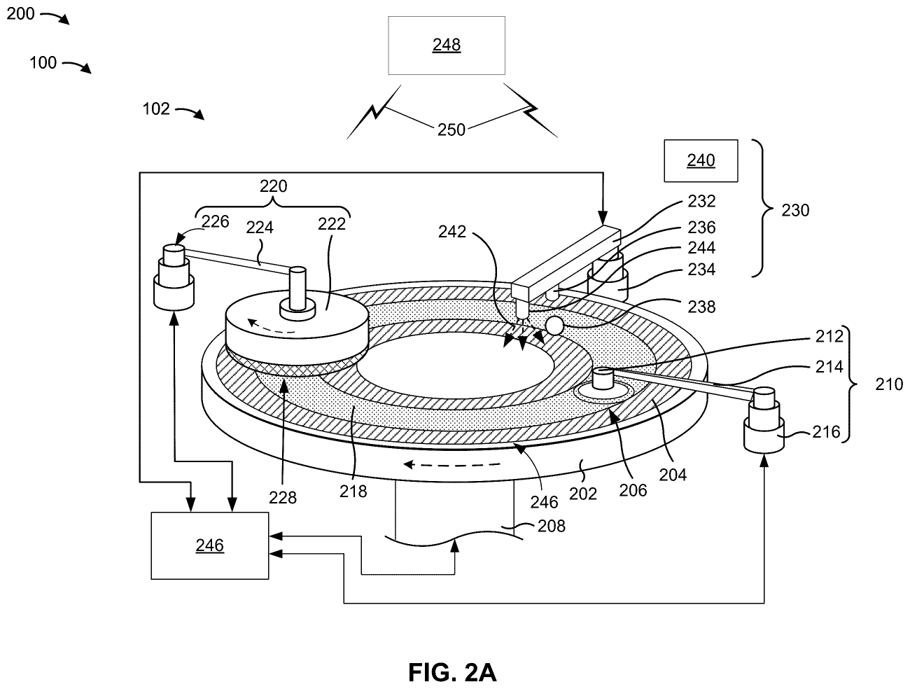

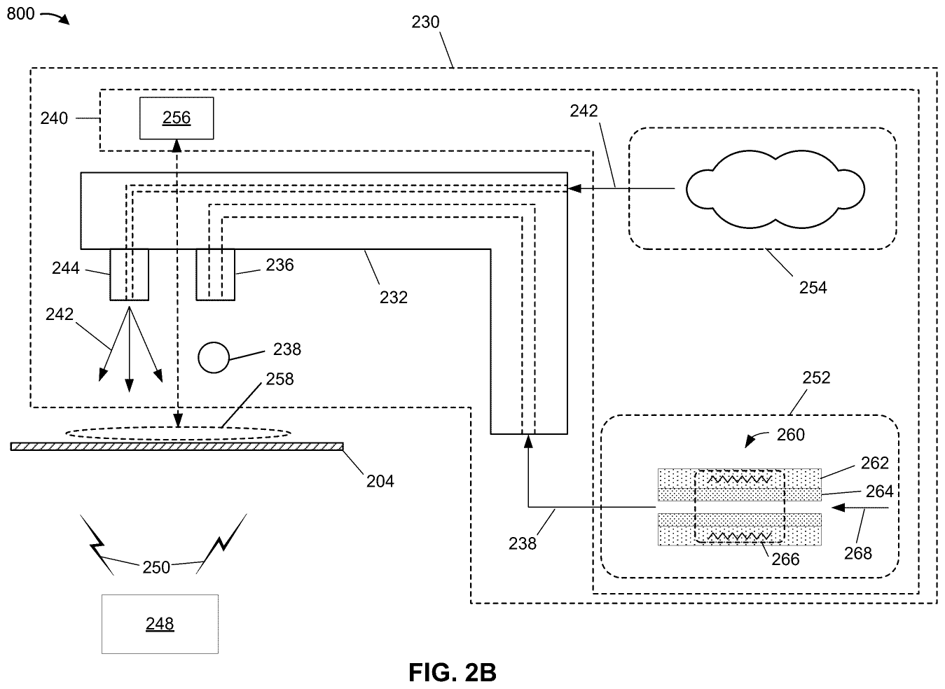

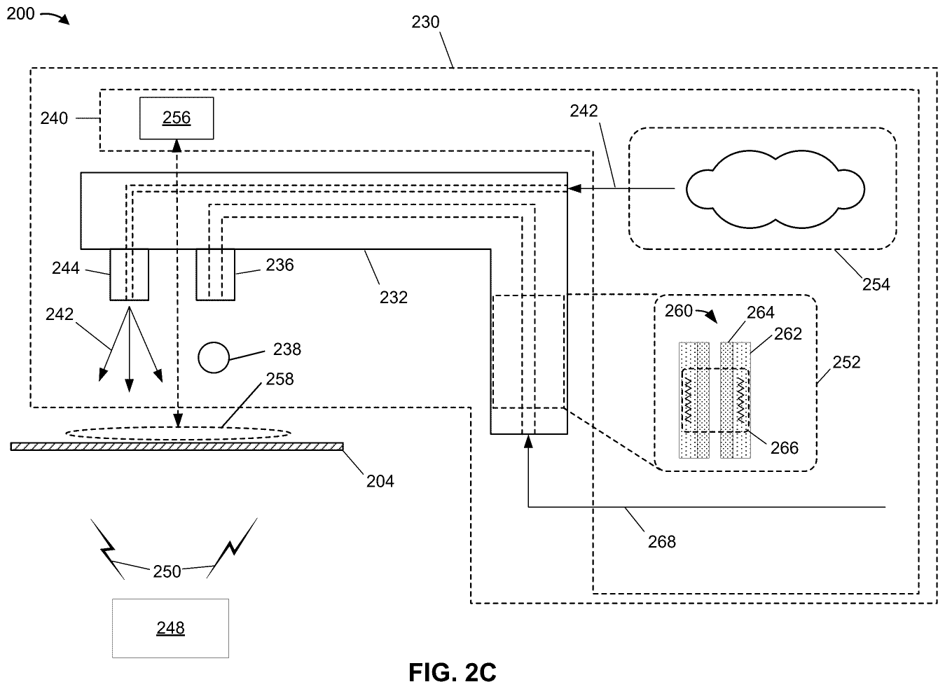

FIGS. 2A-2C are diagrams of an example implementation 200 of the planarization tool 100 described herein. In particular, FIGS. 2A-2C illustrate views of one or more components of the planarization tool 100 that may be in the processing chamber 102.

As shown in FIG. 2A, the planarization tool 100 includes a rotating platen 202 and a polishing pad 204. The polishing pad 204 is mounted on the rotating platen 202 and has a polishing surface 206. The rotating platen 202 is further coupled to a drive shaft 208. The planarization tool 100 further includes a conditioner system 210 having a conditioning disk 212 which can be pivoted via a dispense arm 214. The arm 214 is driven by a shaft 216 to move, for example, in a swing motion over a range 218 in a planarization operation (e.g., a CMP operation). Therefore, the conditioning disk 212 travels along the swing motion to condition different portions of the polishing surface 206. The conditioning disk 212 may be configured to rotate about an axis to restore asperities to the polishing surface 206 as the planarization operation makes the polishing surface 206 smoother. That is, in order to retain the material removal qualities of the polishing pad 204, the conditioning disk 212 is used to maintain roughness on the polishing surface 206 that would otherwise be lost during the planarization operation. The conditioning disk 212 carries an abrasive pad that may include, for example, a diamond abrasive.

The planarization tool 100 includes a wafer carrier system 220 that includes a polishing head 222, an arm 224, and a shaft 226. The polishing head 222 may be used to mount and secure a semiconductor wafer 228. The semiconductor wafer 228 may be mounted and secured to the polishing head 222 by an electrostatic force or another type of securing force. The semiconductor wafer 228 is mounted to the polishing head 222 such that a surface of the semiconductor wafer 228 (e.g., a polishing surface, a processing surface, an active surface, a device surface) that is to be processed is orientated to face the polishing surface 206. The polishing head 222 may also be pivoted via the arm 224. In some implementations, the arm 224 is driven by the shaft 226 to move in a swing motion during the planarization operation. The polishing head 222 is configured to rotate about an axis of the polishing head 222 (e.g., an axis that is approximately perpendicular to the polishing surface 206) in the planarization operation.

As shown in FIG. 2A, the planarization tool 100 includes a slurry dispense system 230. The slurry dispense system 230 includes a dispense arm 232 that is connected to a shaft 234. In some implementations, the dispense arm 232 is driven by the shaft 234 to move in a swing motion in the planarization operation.

The slurry dispense system 230 further includes a slurry dispense nozzle 236 that is connected to the dispense arm 232. The slurry dispense nozzle 236 dispenses heated slurry 238 onto the polishing surface 206 of the polishing pad 204 during a planarization operation. The heated slurry 238 may include an abrasive compound and a fluid such as deionized water, or a liquid cleaner such as potassium hydroxide (KOH), among other examples.

The slurry dispense system 230 further includes a slurry temperature control system 240. The slurry temperature control system 240 may heat and/or control a temperature of the heated slurry 238 as part of the planarization operation. As described in greater detail in connection with FIG. 2B, the slurry temperature control system 240 may include an electro-thermal heat source that provides the heated slurry 238. Additionally, or alternatively, the slurry temperature control system 240 may include a heated fluid supply that provides a heated fluid 242 (e.g., a heated vapor such as superheated steam or a heated gas such as heated nitrogen, among other examples) through a fluid dispersion nozzle 244 proximate to a slurry mixture on a surface of the polishing pad 204 (e.g., a slurry mixture including an accumulation of slurry utilized as part of the planarization operation, including slurry that may have cooled after being dispensed and that is mixed with the heated slurry 238). In some implementations, and as shown in FIG. 2A, the fluid dispersion nozzle 244 is connected to the dispense arm 232. Alternatively, the fluid dispersion nozzle 244 may be supported and/or connected to other components within the processing chamber 102.

As shown in FIG. 2A, the planarization tool 100 includes a motor system 246. The motor system 246 may mechanically couple with the drive shaft 208 to control a direction and/or rate of rotation of the rotating platen 202. Additionally, or alternatively, the motor system 246 may mechanically couple with the shaft 216 to control a swing motion of the conditioning disk 212. Additionally, or alternatively, the motor system 246 may mechanically couple with the shaft 226 to control a swing motion of the polishing head 222. Additionally, or alternatively, the motor system 246 may mechanically couple with the shaft 234 to control a swing motion of the dispense arm 232, including the slurry dispense nozzle 236 and/or the fluid dispersion nozzle 244.

As shown in FIG. 2A, the planarization tool 100 includes a controller 248. The controller 248 (e.g., a processor, a combination of a processor and memory, among other examples) may communicate with the slurry temperature control system 240 and/or the motor system 246 using one or more communication links 250. The one or more communication links 250 may include or more wireless-communication links, one or more wired-communication links, or a combination of one or more wireless-communication links and one or more wired-communication links, among other examples. In some implementations, the controller 248 is separate from the planarization tool 100.

FIG. 2B shows an example implementation of the slurry dispense system 230 that includes the slurry temperature control system 240. As shown in FIG. 2B, the slurry temperature control system 240 includes a slurry heating component 252, a heated fluid supply system 254, and a temperature sensor 256. The slurry temperature control system 240 may control a temperature of a slurry mixture 258 on the polishing pad 204.

As part of the slurry heating component 252, a coaxial heat transfer structure 260 includes a jacket 262 that surrounds a slurry supply line 264. The jacket 262 may be a thermally conductive material that includes a metal material such as a stainless-steel material (SS), an aluminum material (Al), or a copper material (Cu), among other examples.

The slurry supply line 264 may include a material that is resistant to one or more chemicals included in a slurry (e.g., the heated slurry 238). Additionally, or alternatively, the slurry supply line 264 may include a material that is acid and/or alkali resistant. Additionally, or alternatively, the slurry supply line 264 may include a material that is resistant to an elevated temperature (e.g., approximately 80 degrees Celsius (° C.), among other examples). Such a material may correspond to a polytetrafluoroethylene material (PTFE), a polyethylene material (PE), a polypropylene material (PP), a polyvinylidene fluoride material (PVDF), a polyetheretherketone material (PEEK), or a ceramic material, among other examples.

As shown in FIG. 2B, an electro-thermal heating component 266 is thermally coupled with the jacket 262. The electro-thermal heating component 266 may include one or more resistive heating elements (e.g., thermo resistors) that include a nickel chromium material (NiCr), a tungsten material (W), a copper nickel material (CuNi), or an iron-chromium-aluminum material (FeCrAl), among other examples. In some implementations, the electro-thermal heating component 266 is embedded in the jacket 262. Alternatively, and in some implementations, the electro-thermal heating component 266 is on the jacket 262.

In some implementations, a material of the slurry supply line 264 may be enhanced to increase thermal conductivity and/or transfer of heat generated by the electro-thermal heating component 266. For example, and in a case where the material of the slurry supply line 264 includes a PTFE matrix, conductive particulates (e.g., fillers) such as carbon, graphite, glass fibers, and/or bronze may be added to the PTFE matrix to increase thermal conductivity, thereby enabling the slurry supply line 264 to transfer heat generated by the electro-thermal heating component 266.

In FIG. 2B, an unheated slurry 268 enters the coaxial heat transfer structure 260 and exits the coaxial heat transfer structure 260 as the heated slurry 238. The heated slurry 238 then enters a conduit (e.g., a lined passageway, an unlined passageway, or a tube) in the slurry dispense arm 232 for dispensing through the slurry dispense nozzle 236.

As shown in FIG. 2B, the slurry heating component 252 is included as part of the slurry dispense system 230 (e.g., the coaxial heat transfer structure 260 including the jacket 262 and the electro-thermal heating component 266 are integrated with the slurry supply line 264 within the planarization tool 100). However, in some implementations, the slurry heating component 252 may be remote from the slurry dispense system 230 (e.g., integrated with the slurry supply line in a plenum separate from the planarization tool 100).

The heated fluid supply system 254 may include different subsystems and/or components based on a type of fluid that is heated. As an example, and in some implementations, the heated fluid supply system 254 includes a superheated steam generator subsystem to vaporize deionized water into superheated steam and one or more valve components that control a flow rate of the superheated steam. Alternatively, and in some implementations, the heated fluid supply system 254 includes a convective heat transfer subsystem to heat a gas (e.g., nitrogen) and one or more valve components that control a flow rate of the heated gas. Further, and although shown to be part of the slurry dispense system 230, in some implementations the heated fluid supply system 254 may be separate from the slurry dispense system 230 (e.g., separate from the planarization tool 100).

As shown in FIG. 2B, the heated fluid 242 exits the heated fluid supply system 254 and enters a conduit (e.g., a lined passageway, an unlined passageway, or a tube) in the slurry dispense arm 232 for dispersion through the fluid dispersion nozzle 244 proximate the slurry mixture 258 and/or the slurry dispense nozzle 236. However, in some implementations, the heated fluid 242 may enter another conduit that is separate from the slurry dispense arm 232 for dispersion proximate the slurry mixture 258 and/or the slurry dispense nozzle 236.

The temperature sensor 256 may be a thermal sensor such as an infrared (IR) sensor, among other examples. In some implementations, the temperature sensor 256 is configured to monitor a temperature of the slurry mixture 258. Additionally, or alternatively, and in some implementations, the temperature sensor 256 is configured to monitor a temperature of the polishing pad 204.

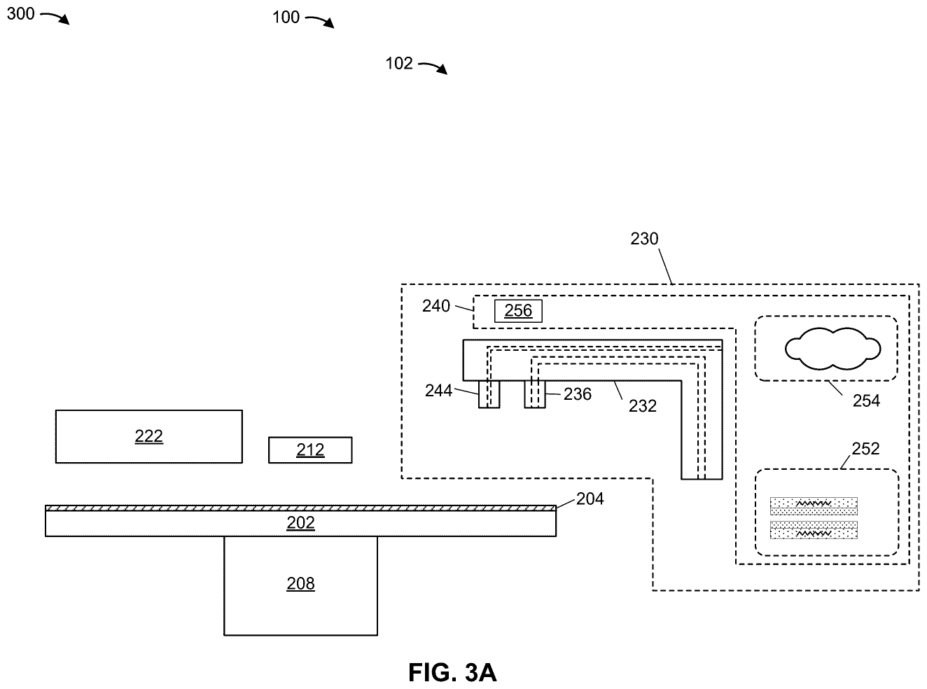

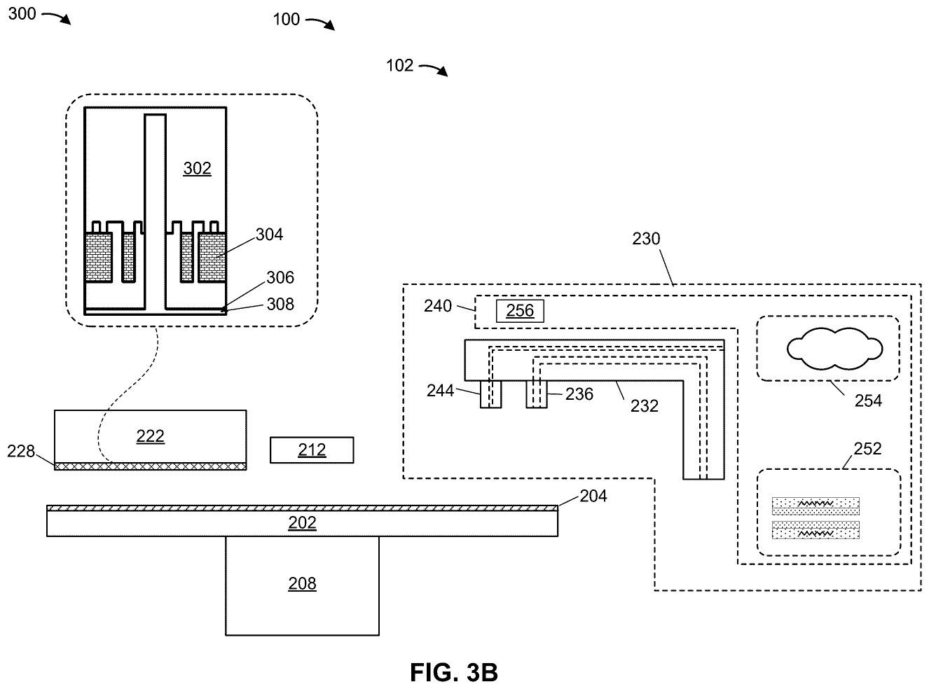

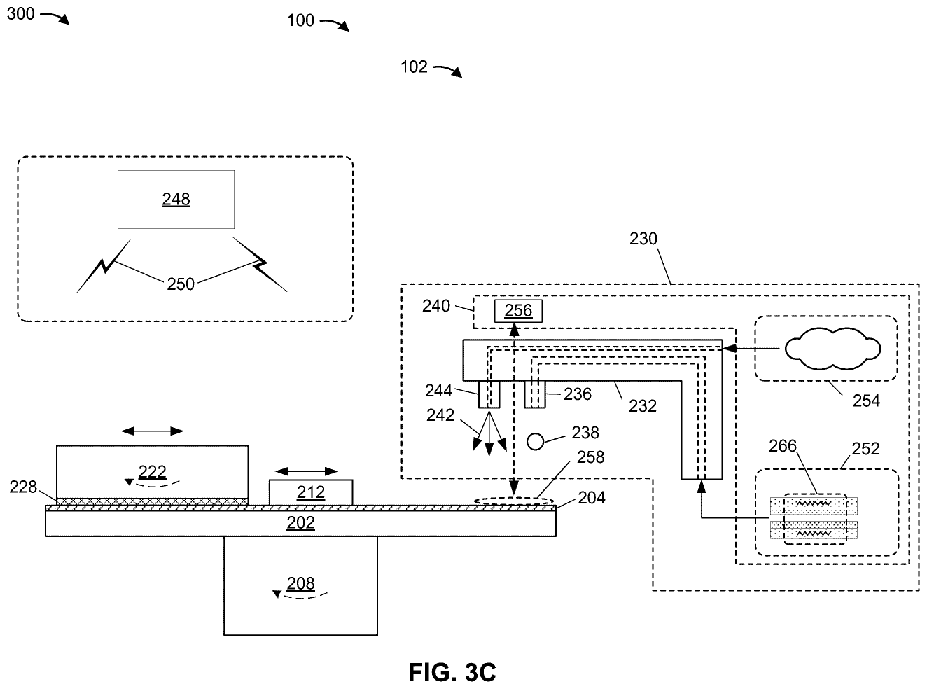

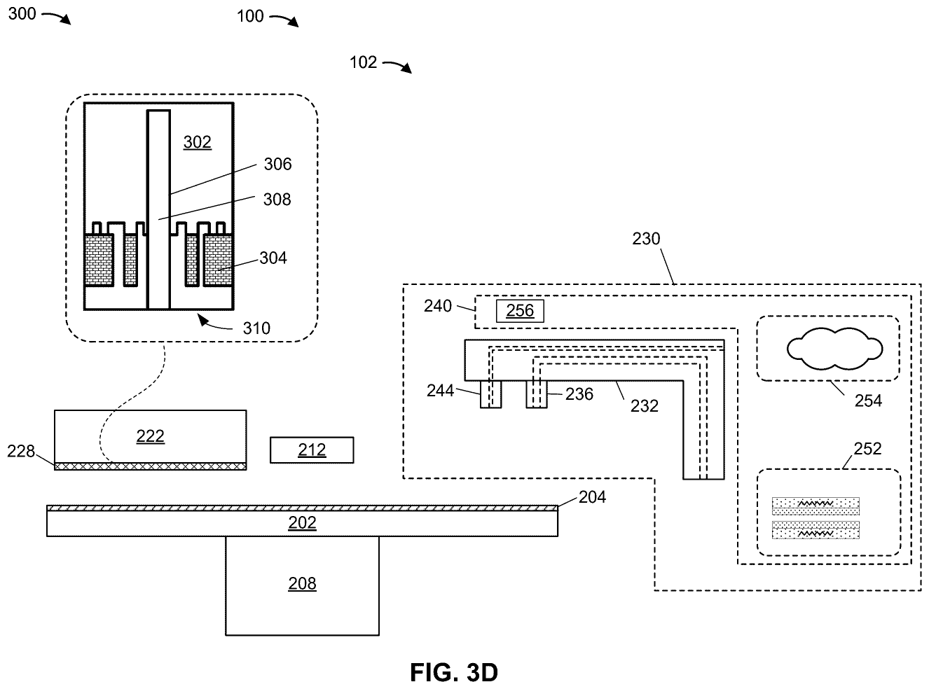

As described in greater detail in connection with FIGS. 3A-3D, and as part of a closed-loop heating system, the controller 248 may use the one or more communication links 250 to receive information from the temperature sensor 256 (e.g., information related to a temperature of the polishing pad 204 and/or the slurry mixture 258). Based on the information, the controller 248 may make one or more determinations related to the planarization operation and use the one or more communication links 250 to communicate with the slurry temperature control system 240 to adjust a setting. As an example, adjusting a setting may include adjusting a setting of the slurry heating component 252 that controls a temperature of the heated slurry 238. Additionally, or alternatively, adjusting a setting may include adjusting a setting of the heated fluid supply system 254 that controls a flow rate of the heated fluid 242.

FIG. 2C shows another example configuration of the slurry dispense system 230 that includes the slurry temperature control system 240. In contrast to the configuration of the slurry dispense system 230 described in connection with FIG. 2B, the configuration of FIG. 2C includes the coaxial heat transfer structure 260 (e.g., the electro-thermal heating component 266) embedded in the slurry dispense arm 232. Additionally, or alternatively and in some implementations, the coaxial heat transfer structure 260 covers a portion or substantially all of a path taken by the slurry 268 and/or the heated slurry 238 towards the slurry dispense nozzle 236 within the slurry dispense arm 232.

As described in connection with FIGS. 2A-2C, and in some implementations, a planarization tool (e.g., the planarization tool 100) includes a polishing pad (e.g., the polishing pad 204). The planarization tool includes a slurry temperature control system (e.g., the slurry temperature control system 240) that includes a slurry heating component (e.g., the slurry heating component 252) and a temperature sensor (e.g., the temperature sensor 256) configured to monitor a temperature of a slurry mixture (e.g., the slurry mixture 258) on the polishing pad in a planarization operation. The planarization tool includes a controller (e.g., the controller 248) configured to adjust a setting, of the slurry heating component, that controls a temperature of a heated slurry based on information received from the temperature sensor.

As indicated above, FIGS. 2A-2C are provided as examples. Other examples may differ from what is described with regard to FIGS. 2A-2C.

FIGS. 3A-3D are diagrams of an example implementation 300 of a planarization tool described herein. The planarization tool of FIGS. 3A-3D may correspond to the planarization tool 100.

FIG. 3A shows the processing chamber 102 in the planarization tool 100, including the rotating platen 202, the polishing pad 204, the drive shaft 208, the conditioning disk 212, and the polishing head 222. FIG. 3A further shows the slurry dispense system 230 and the slurry dispense arm 232. The slurry dispense system 230 includes the slurry heating component 252, the heated fluid supply system 254, and the temperature sensor 256. The slurry dispense nozzle 236 and the fluid dispersion nozzle 244 are on the slurry dispense arm 232.

Turning to FIG. 3B, the semiconductor wafer 228 is received onto the polishing head 222. In some implementations, the polishing head 222 uses an electrostatic chuck (ESC) or a vacuum chuck to secure the semiconductor wafer 228 to the polishing head 222.

As shown in FIG. 3B, and as an example, the semiconductor wafer 228 may include a silicon substrate 302 and a device region 304 (e.g., integrated circuitry formed on the silicon substrate 302). In some implementations, and as part of forming an interconnect structure (e.g., a through silicon vertical interconnect access structure, or TSV structure), the semiconductor wafer 228 may include one or more liner layers 306 (e.g., one or more dielectric layers) and a conductive layer 308 (e.g., a metallization layer) over the liner layer(s) 306. The liner layer(s) 306 and the conductive layer 308 may include portions that penetrate into the silicon substrate 302 via the interconnect structure and portions that are formed across a surface of the device region 304.

Turning to FIG. 3C, the planarization tool 100 performs a planarization operation. Performing the planarization operation may include the polishing head 222 pressing the semiconductor wafer 228 against the polishing pad 204. Additionally, or alternatively, performing the planarization operation may include rotating the drive shaft 208, laterally moving (e.g., sweeping) the conditioning disk 212, rotating the polishing head 222, and/or laterally moving the polishing head 222.

As shown in FIG. 3C, and as part of the planarization operation, the heated slurry 238 is dispensed onto the polishing pad 204 through the slurry dispense nozzle 236. Furthermore, the heated fluid 242 is dispersed through the fluid dispersion nozzle 244 in a region that is proximate to the slurry dispense nozzle 236 and/or the slurry mixture 258.

In some implementations and as part of a closed-loop system, the temperature sensor 256 monitors a temperature of the slurry mixture 258. Additionally, or alternatively and in some implementations as part of the closed-loop system, the temperature sensor 256 monitors a temperature of the polishing pad 204.

The controller 248 may communicate with one or more components of the slurry dispense system 230 to control a temperature of the slurry mixture 258 on the polishing pad 204 during the planarization operation. For example, using information received from the temperature sensor 256, the controller 248 may determine that a temperature of the slurry mixture 258 does not satisfy a threshold associated with an optimized polishing rate (e.g., an optimized removal rate of portions of the liner layer(s) 306 and/or the conductive layer 308 across the surface of the device region 304 of the semiconductor wafer 228 as described in connection with FIG. 3B). Based on such a determination, the controller 248 may communicate with the slurry heating component 252 to adjust a setting that increases an amount of power supplied to the electro-thermal heating component 266 to increase a temperature of the heated slurry 238. Additionally, or alternatively, the controller 248 may communicate with the heated fluid supply system 254 to adjust a setting that increases a flow rate of the heated fluid 242 to increase an amount of heat transferred to the slurry mixture 258 and/or the polishing pad 204.

In some implementations the controller 248 may determine adjustments to one or more settings using a machine learning model. The machine learning model may include and/or may be associated with one or more of a neural network model, a random forest model, a clustering model, or a regression model, among other examples. In some implementations, the controller 248 uses the machine learning model to determine adjustments by providing candidate temperature parameters (e.g., temperatures of the polishing pad 204 and/or the slurry mixture 258), flow rate parameters (e.g., flow rate of the heated fluid 242), rotational velocity parameters (e.g., rotational velocities of the polishing head 222 and/or the drive shaft 208), material parameters (e.g., a type of the material in the liner layer(s) 306 and/or the conductive layer 308), compressive force parameters (e.g., a compressive force provided by the polishing head 222 that presses the semiconductor wafer 228 against the polishing pad 204), and/or slurry composition parameters (e.g., chemical mixtures and/or percentages included in the heated slurry 238) as inputs to the machine learning model, and using the machine learning model to determine a likelihood, probability, or confidence that a particular outcome (e.g., removal rate and/or surface finish) for a subsequent planarization operation will be achieved using the candidate parameters. In some implementations, the controller 248 provides a removal rate and/or a surface finish as input to the machine learning model, and the controller 248 uses the machine learning model to determine or identify a particular combination of temperature parameters, rotational velocity parameters, flow rate parameters, material parameters, compressive force parameters, and/or slurry composition parameters that are likely to achieve the removal rate and/or surface finish.

The controller 248 (or another system) may train, update, and/or refine the machine learning model to increase the accuracy of the outcomes and/or parameters determined using the machine learning model. The controller 248 may train, update, and/or refine the machine learning model based on feedback and/or results from the subsequent planarization operation, as well as from historical or related planarization operations (e.g., from hundreds, thousands, or more historical or related planarization operations) performed by the planarization tool 100.

Turning to FIG. 3D, the polishing head 222 removes the semiconductor wafer 228 from the polishing pad 204. As shown in FIG. 3D, portions of the liner layer 306 and the conductive layer 308 that span the device region 304 have been removed to expose a surface 310 of the device region 304.

As described in connection with FIGS. 3A-3D, and in some implementations, a planarization tool (e.g., the planarization tool 100) performs a series of operations. The series of operations includes securing a semiconductor wafer (e.g., the semiconductor wafer 228) to a polishing head (e.g., the polishing head 222) in a processing chamber (e.g., the processing chamber 102) of the planarization tool. The series of operations includes dispensing, using a slurry dispense nozzle (e.g., the slurry dispense nozzle 236), a heated slurry (e.g., the heated slurry 238) onto a polishing pad (e.g., the polishing pad 204) in the processing chamber. The series of operations includes pressing, using the polishing head, the semiconductor wafer against the polishing pad to planarize a layer (e.g., the conductive layer 308 and/or the liner layer 306) on the semiconductor wafer in a planarization operation that uses a slurry mixture (e.g., the slurry mixture 258) on the polishing pad that includes the heated slurry.

Additionally, or alternatively and in some implementations, a planarization tool (e.g., the planarization tool 100) performs a series of operations. The series of operations includes securing a semiconductor wafer (e.g., the semiconductor wafer 228) to a polishing head (e.g., the polishing head 222) in a processing chamber (e.g., the processing chamber 102) of the planarization tool. The series of operations includes pressing, using the polishing head, the semiconductor wafer against a polishing pad (e.g., the polishing pad 204) in the processing chamber to planarize a layer (e.g., the conductive layer and/or the liner layer 306) on the semiconductor wafer in a planarization operation. The series of operations includes monitoring, using a temperature sensor (e.g., the temperature sensor 256), a temperature of a slurry mixture (e.g., the slurry mixture 258) on the polishing pad that is used in the planarization operation. The series of operations includes adjusting, by a controller (e.g., the controller 248), one or more settings related to the planarization operation based on information received from the temperature sensor.

In this way, a utilization of the planarization tool is improved, an amount of wasted slurry is reduced, or a yield of semiconductor devices from the semiconductor wafer is increased. Furthermore, an amount of resources used to fabricate a volume of the semiconductor devices (e.g., semiconductor processing tools, labor, raw materials, and/or computing resources) is reduced.

As indicated above, FIGS. 3A-3D are presented as an example. Other examples may differ from what is described with regard to FIGS. 3A-3D.

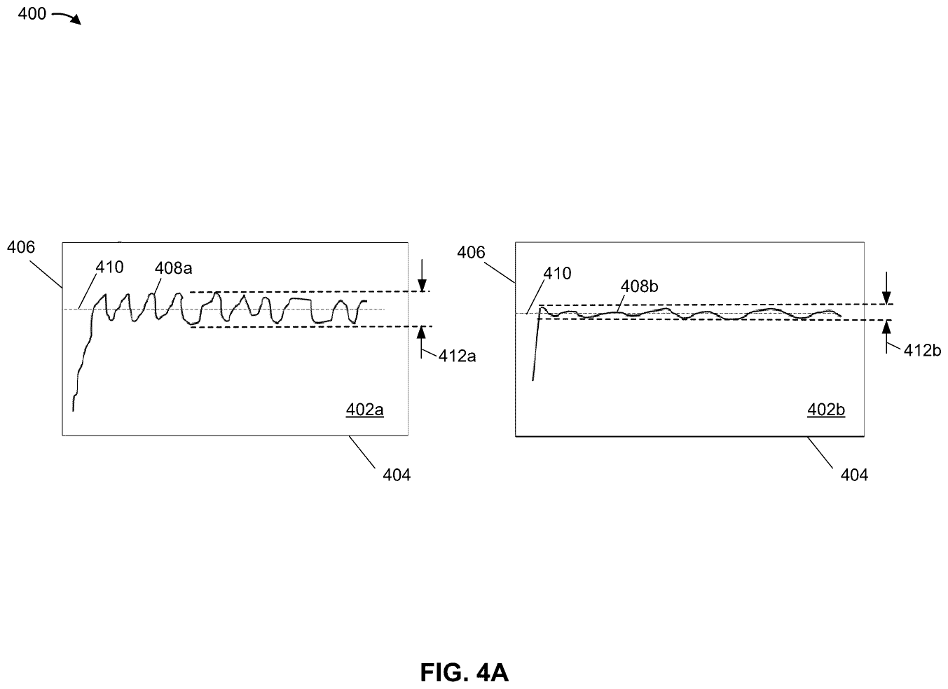

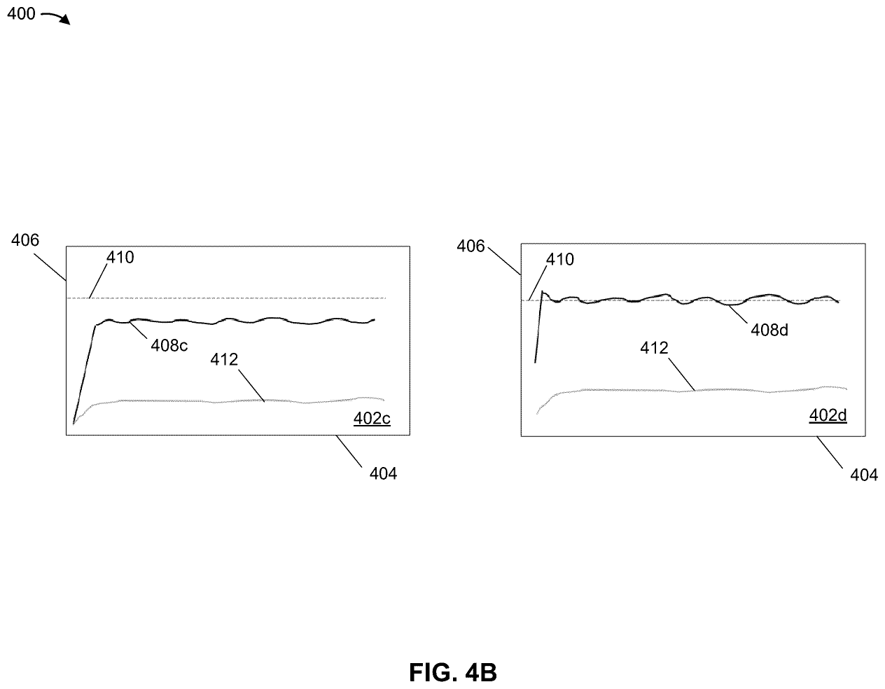

FIGS. 4A and 4B are diagrams of example performance data 400 described herein. The performance data 400 may contrast performance data of an implementation of a planarization tool that includes an open-loop heating system with a single heating source (e.g., a vapor heating source) versus an implementation of a planarization tool that includes a closed-loop heating system with two heating sources (e.g., the planarization tool 100 including the slurry dispense system 230 having the slurry heating component 252, the heated fluid supply system 254, and the temperature sensor 256 as described in connection with FIGS. 1-3D). In each of FIGS. 4A-4B, a chart 402 shows a time 404 versus temperature 406 relationship associated with a temperature response 408 for a slurry mixture on a polishing pad (e.g., the slurry mixture 258 on the polishing pad 204). The temperature response 408 is shown relative to a target temperature 410 for the slurry mixture on the polishing pad.

As shown in FIG. 4A, chart 402a shows an example temperature response 408a for the planarization tool including the open-loop heating system with the single heating source. In contrast, chart 402b shows an example temperature response 408b for the planarization tool having the closed-loop heating system with two heating sources. As shown in FIG. 4A, a variation 412a associated with the temperature response 408a is substantially greater than the variation 412b associated with the temperature response 408b. In other words, the planarization tool having the closed-loop heating system with two heating sources has a control over a temperature of the slurry mixture that is increased relative to a planarization tool having the open-loop heating system with one heating source. Such an increased control may correspond to an improved planarity (e.g., a “flatness”) of a semiconductor wafer processed by the planarization tool having the closed-loop heating system with two heating sources.

As shown in FIG. 4B, chart 402c shows an example temperature response 408c for the planarization tool including the open-loop heating system with the single heating source. In contrast, chart 402d shows an example temperature response 408d for the planarization tool having the closed-loop heating system with two heating sources. Charts 402c and 402d each includes temperature response data 412 for a planarization tool not including a heating system. As shown in FIG. 4B, the temperature response 408d is substantially closer to the target temperature 410 than the temperature response 408c. In other words, the planarization tool having the closed-loop heating system with two heating sources has an ability to achieve the target temperature 410 of the slurry mixture that is increased relative to a planarization tool having the open-loop heating system with one heating source. Such an increased ability may correspond to an improved removal rate of a material from a semiconductor wafer (e.g., the liner layer 306 and/or the conductive layer 308) to increase a utilization rate of the planarization tool.

As indicated above, FIGS. 4A and 4B are presented as one or more examples. Other examples may differ from what is described with regard to FIGS. 4A and 4B.

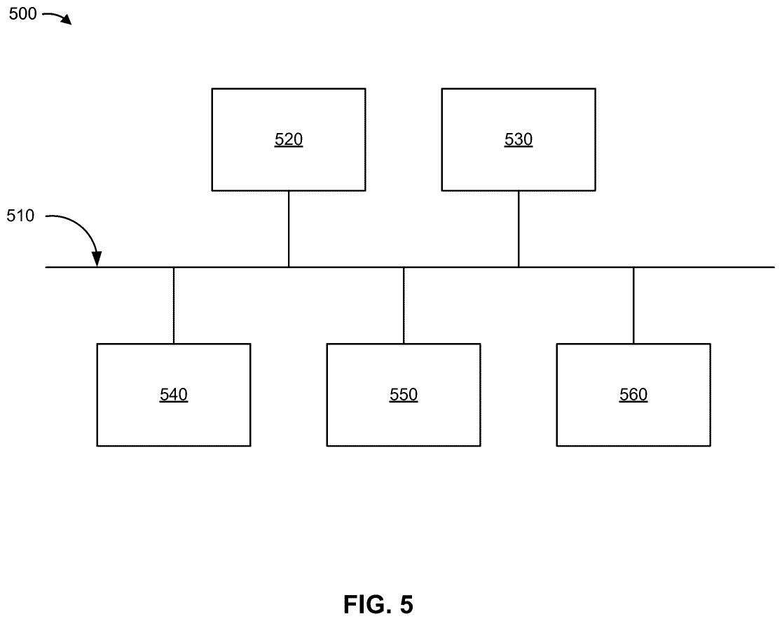

FIG. 5 is a diagram of example components of a device 500 described herein. The device 500 may correspond to the planarization tool 100 or components of the planarization tool 100, such as the slurry dispense system 230 (e.g., the slurry heating component 252, the heated fluid supply system 254, and/or the temperature sensor 256), the motor system 246, and/or the controller 248. In some implementations, the planarization tool 100 or components of the planarization tool 100, such as the slurry dispense system 230 (e.g., the slurry heating component 252 and/or the temperature sensor 256), the motor system 246, and/or the controller 248 may include one or more devices 500 and/or one or more components of the device 500. As shown in FIG. 5, the device 500 may include a bus 510, a processor 520, a memory 530, an input component 540, an output component 550, and/or a communication component 560.

The bus 510 may include one or more components that enable wired and/or wireless communication among the components of the device 500. The bus 510 may couple together two or more components of FIG. 5, such as via operative coupling, communicative coupling, electronic coupling, and/or electric coupling. For example, the bus 510 may include an electrical connection (e.g., a wire, a trace, and/or a lead) and/or a wireless bus. The processor 520 may include a central processing unit, a graphics processing unit, a microprocessor, a controller, a microcontroller, a digital signal processor, a field-programmable gate array, an application-specific integrated circuit, and/or another type of processing component. The processor 520 may be implemented in hardware, firmware, or a combination of hardware and software. In some implementations, the processor 520 may include one or more processors capable of being programmed to perform one or more operations or processes described elsewhere herein.

The memory 530 may include volatile and/or nonvolatile memory. For example, the memory 530 may include random access memory (RAM), read only memory (ROM), a hard disk drive, and/or another type of memory (e.g., a flash memory, a magnetic memory, and/or an optical memory). The memory 530 may include internal memory (e.g., RAM, ROM, or a hard disk drive) and/or removable memory (e.g., removable via a universal serial bus connection). The memory 530 may be a non-transitory computer-readable medium. The memory 530 may store information, one or more instructions, and/or software (e.g., one or more software applications) related to the operation of the device 500. In some implementations, the memory 530 may include one or more memories that are coupled (e.g., communicatively coupled) to one or more processors (e.g., processor 520), such as via the bus 510. Communicative coupling between a processor 520 and a memory 530 may enable the processor 520 to read and/or process information stored in the memory 530 and/or to store information in the memory 530.

The input component 540 may enable the device 500 to receive input, such as user input and/or sensed input. For example, the input component 540 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 550 may enable the device 500 to provide output, such as via a display, a speaker, and/or a light-emitting diode. The communication component 560 may enable the device 500 to communicate with other devices via a wired connection and/or a wireless connection. For example, the communication component 560 may include a receiver, a transmitter, a transceiver, a modem, a network interface card, and/or an antenna.

The device 500 may perform one or more operations or processes described herein. For example, a non-transitory computer-readable medium (e.g., memory 530) may store a set of instructions (e.g., one or more instructions or code) for execution by the processor 520. The processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry may be used instead of or in combination with the instructions to perform one or more operations or processes described herein. Additionally, or alternatively, the processor 520 may be configured to perform one or more operations or processes described herein. Thus, implementations described herein are not limited to any specific combination of hardware circuitry and software.

The number and arrangement of components shown in FIG. 5 are provided as an example. The device 500 may include additional components, fewer components, different components, or differently arranged components than those shown in FIG. 5. Additionally, or alternatively, a set of components (e.g., one or more components) of the device 500 may perform one or more functions described as being performed by another set of components of the device 500.

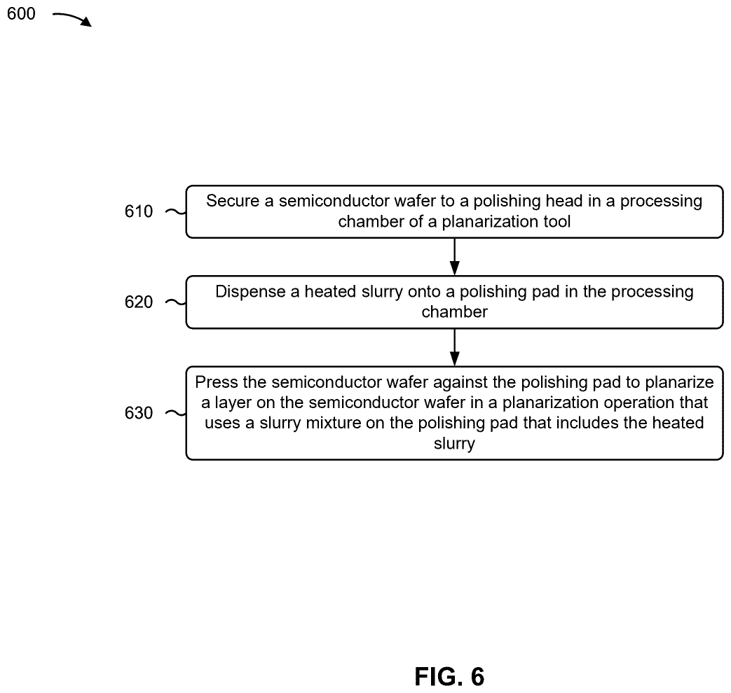

FIG. 6 is a flowchart of an example process 600 described herein. In some implementations, one or more process blocks of FIG. 6 are performed by the planarization tool 100. In some implementations, one or more process blocks of FIG. 6 are performed by another device or a group of devices separate from or including the planarization tool 100, such as the slurry dispense system 230 (e.g., the slurry heating component 252 and/or the temperature sensor 256), the motor system 246, and/or the controller 248. Additionally, or alternatively, one or more process blocks of FIG. 6 may be performed by one or more components of device 500, such as processor 520, memory 530, input component 540, output component 550, and/or communication component 560.

As shown in FIG. 6, process 600 may include securing a semiconductor wafer to a polishing head in a processing chamber of a planarization tool (block 610). For example, a planarization tool (e.g., the planarization tool 100) may secure a semiconductor wafer (e.g., the semiconductor wafer 228) to a polishing head (e.g., the polishing head 222) in a processing chamber (e.g., the processing chamber 102) of the planarization tool, as described above.

As further shown in FIG. 6, process 600 may include dispensing, using a slurry dispense nozzle, a heated slurry onto a polishing pad in the processing chamber (block 620). For example, a slurry dispense system (e.g., the slurry dispense system 230) may dispense, using a slurry dispense nozzle (e.g., the slurry dispense nozzle 236), a heated slurry (e.g., the heated slurry 238) onto a polishing pad (e.g., the polishing pad 204) in the processing chamber, as described above.

As further shown in FIG. 6, process 600 may include pressing, using the polishing head, the semiconductor wafer against the polishing pad to planarize a layer on the semiconductor wafer in a planarization operation that uses a slurry mixture on the polishing pad that includes the heated slurry (block 630). For example, a motor system (e.g., the motor system 246) may press, using the polishing head, the semiconductor wafer against the polishing pad to planarize a layer (e.g., the conductive layer 308) on the semiconductor wafer in a planarization operation that uses a slurry mixture (e.g., the slurry mixture 258) on the polishing pad that includes the heated slurry, as described above.

Process 600 may include additional implementations, such as any single implementation or any combination of implementations described below and/or in connection with one or more other processes described elsewhere herein.

In a first implementation, process 600 includes receiving, using a controller (e.g., the controller 248), information related to a temperature of the slurry mixture on the polishing pad, and adjusting, using the controller, a setting that controls a temperature of the heated slurry based on the information.

In a second implementation, alone or in combination with the first implementation, adjusting the setting that controls a temperature of the heated slurry includes adjusting a setting of an electro-thermal heating component (e.g., the electro-thermal heating component 266) of a slurry heating component (e.g., the slurry heating component 252) that provides the heated slurry.

In a third implementation, alone or in combination with one or more of the first and second implementations, process 600 includes dispensing, using a fluid dispersion nozzle (e.g., the fluid dispersion nozzle 244), a heated fluid (e.g., the heated fluid 242) proximate the slurry mixture.

In a fourth implementation, alone or in combination with one or more of the first through third implementations, process 600 includes receiving, using a controller (e.g., the controller 248), information related to a temperature of the slurry mixture on the polishing pad, and adjusting, using the controller, a setting of a heated fluid supply system (e.g., the heated fluid supply system 254) that provides the heated fluid based on the information.

In a fifth implementation, alone or in combination with one or more of the first through fourth implementations, adjusting the setting of the heated fluid supply system includes adjusting a setting that controls a temperature of the heated fluid.

In a sixth implementation, alone or in combination with one or more of the first through fifth implementations, adjusting the setting of the heated fluid supply system includes adjusting a setting that controls a flow rate of the heated fluid.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

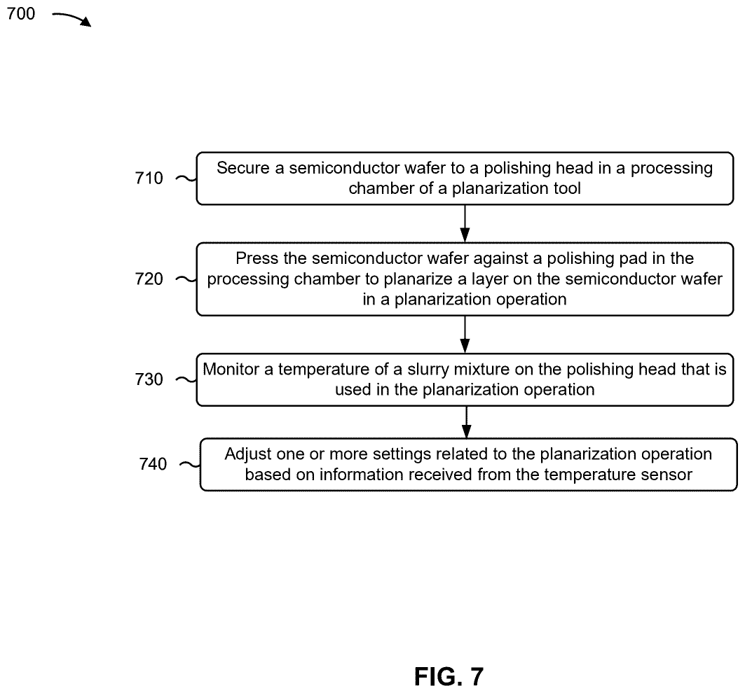

FIG. 7 is a flowchart of an example process 700 described herein. In some implementations, one or more process blocks of FIG. 7 are performed by the planarization tool 100. In some implementations, one or more process blocks of FIG. 7 are performed by another device or a group of devices separate from or including the planarization tool 100, such as the slurry dispense system 230 (e.g., the slurry heating component 252 and/or the temperature sensor 256), the motor system 246, and/or the controller 248. Additionally, or alternatively, one or more process blocks of FIG. 7 may be performed by one or more components of device 500, such as processor 520, memory 530, input component 540, output component 550, and/or communication component 560.

As shown in FIG. 7, process 700 may include securing a semiconductor wafer to a polishing head in a processing chamber of a planarization tool (block 710). For example, a planarization tool (e.g., the planarization tool 100) may secure a semiconductor wafer (e.g., the semiconductor wafer 228) to a polishing head (e.g., the polishing head 222) in a processing chamber (e.g., the processing chamber 102) of the planarization tool, as described above.

As further shown in FIG. 7, process 700 may include pressing, using the polishing head, the semiconductor wafer against a polishing pad in the processing chamber to planarize a layer on the semiconductor wafer in a planarization operation (block 720). For example, the planarization tool may press, using the polishing head, the semiconductor wafer against a polishing pad (e.g., the polishing pad 204) in the processing chamber to planarize a layer (e.g., the conductive layer 308, the liner layer 306) on the semiconductor wafer in a planarization operation, as described above.

As further shown in FIG. 7, process 700 may include monitoring, using a temperature sensor, a temperature of a slurry mixture on the polishing pad that is used in the planarization operation (block 730). For example, the planarization tool may monitor, using a temperature sensor (e.g., the temperature sensor 256), a temperature of a slurry mixture (e.g., the slurry mixture 258) on the polishing head that is used in the planarization operation, as described above.

As further shown in FIG. 7, process 700 may include adjusting one or more settings related to the planarization operation based on information received from the temperature sensor (block 740). For example, a controller (e.g., the controller 248) may adjust one or more settings related to the planarization operation based on information received from the temperature sensor, as described above.

Process 700 may include additional implementations, such as any single implementation or any combination of implementations described below and/or in connection with one or more other processes described elsewhere herein.

In a first implementation, adjusting the one or more settings related to the planarization operation includes adjusting a setting of a slurry heating component (e.g., the slurry heating component 252) that controls a temperature of a heated slurry (e.g., the heated slurry 238) dispensed through a slurry dispense nozzle (e.g., the slurry dispense nozzle 236) onto the polishing head.

In a second implementation, alone or in combination with the first implementation, adjusting the one or more settings related to the planarization operation includes adjusting a setting of a heated fluid supply system (e.g., the heated fluid supply system 254) that controls a temperature of a heated fluid (e.g., the heated fluid 242) dispensed through a fluid dispersion nozzle (e.g., the fluid dispersion nozzle 244) proximate the slurry mixture.

In a third implementation, alone or in combination with one or more of the first and second implementations, adjusting the one or more settings related to the planarization operation includes one or more of adjusting a setting that controls a rotational velocity of the polishing head, or adjusting a setting that controls a compressive force that presses the semiconductor wafer against the polishing pad using the polishing head.

In a fourth implementation, alone or in combination with one or more of the first through third implementations, adjusting the one or more settings related to the planarization operation includes determining at least one parameter related to adjusting the one or more settings using a machine learning model.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

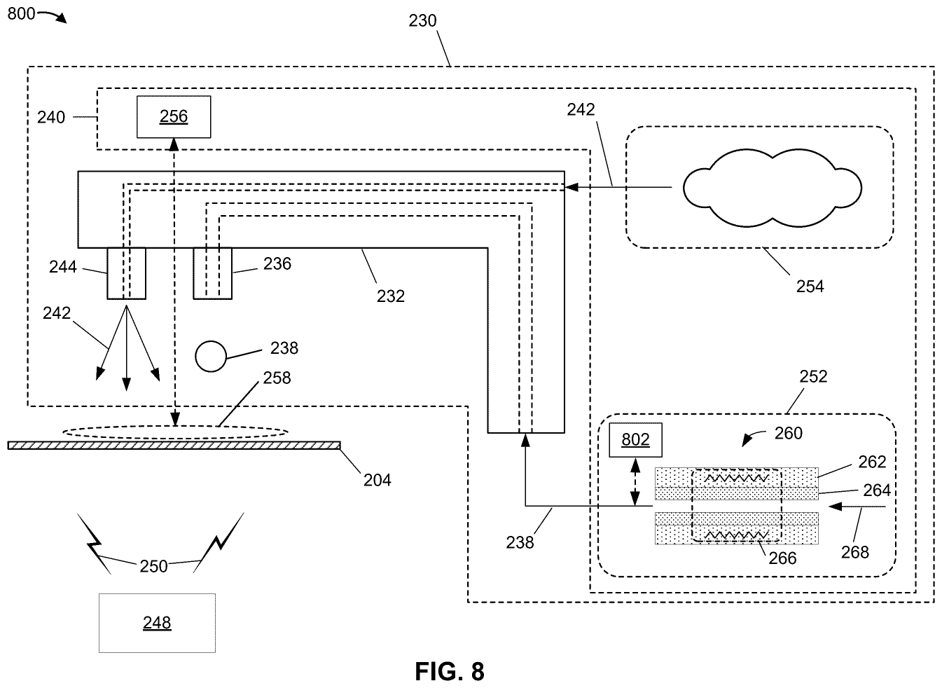

FIG. 8 is a diagram of an example implementation 800 described herein. In contrast to the implementation 200 described in connection with FIGS. 2A-2C, implementation 800 includes a temperature sensor 802 (e.g., an additional temperature sensor) that is part of the slurry heating component 252.

The temperature sensor 802 may be a thermal sensor such as an infrared (IR) sensor, among other examples. In some implementations, the temperature sensor 802 is configured to monitor a temperature of the heated slurry 238 prior the heated slurry 238 entering the dispense arm and/or being dispensed onto the polishing pad 204.

The temperature sensor 802 may provide feedback on the heated slurry 238 to the controller 240. The feedback on the heated slurry 238 may enable the controller 240 to provide enhanced thermal control, augmenting techniques described in connection with FIGS. 2A-7.

As indicated above, FIG. 8 is provided as an example. Other examples may differ from what is described with regard to FIG. 8.

Some implementations described herein provide a planarization tool and methods of operation. The planarization tool includes a closed-loop heating system with two heating sources to control a temperature of a slurry dispensed onto polishing pad as part of a planarization operation. The two heating sources include an electro-thermal system that heats slurry in a slurry line of the planarization tool and a nozzle that emits a heated fluid near a dispense point of the slurry. The closed-loop heating system with the two heating sources further includes a temperature sensor that provides feedback related to a temperature of a mixture of slurry on the polishing pad during the polishing/planarization operation.

Relative to an open-loop heating system using superheated steam, the closed-loop heating system with the two heating sources increases a rate at which a temperature of the slurry is increased to improve a utilization of the planarization tool and/or reduce a waste of the slurry. Additionally, and relative to the open-loop heating system using superheated steam, the closed-loop heating system with the two heating sources improves a control of a temperature of the slurry to reduce variations in a flatness of the semiconductor wafer and improve a yield of semiconductor devices from the semiconductor wafer.

In this way, a utilization of the planarization tool is improved, an amount of wasted slurry is reduced, and/or a yield of semiconductor devices from the semiconductor wafer is increased. Furthermore, an amount of resources used to fabricate a volume of the semiconductor devices (e.g., semiconductor processing tools, labor, raw materials, and/or computing resources) is reduced.

As described in greater detail above, some implementations described herein provide a method. The method includes securing a semiconductor wafer to a polishing head in a processing chamber of a planarization tool. The method includes dispensing, using a slurry dispense nozzle, a heated slurry onto a polishing pad in the processing chamber. The method includes pressing, using the polishing head, the semiconductor wafer against the polishing pad to planarize a layer on the semiconductor wafer in a planarization operation that uses a slurry mixture on the polishing pad that includes the heated slurry.

As described in greater detail above, some implementations described herein provide a method. The method includes securing a semiconductor wafer to a polishing head in a processing chamber of a planarization tool. The method includes pressing, using the polishing head, the semiconductor wafer against a polishing pad in the processing chamber to planarize a layer on the semiconductor wafer in a planarization operation. The method includes monitoring, using a temperature sensor, a temperature of a slurry mixture on the polishing pad that is used in the planarization operation. The method includes adjusting, by a controller, one or more settings related to the planarization operation based on information received from the temperature sensor.

As described in greater detail above, some implementations described herein provide a planarization tool. The planarization tool includes a polishing pad. The planarization tool includes a slurry temperature control system that includes a slurry heating component and a temperature sensor configured to monitor a temperature of a slurry mixture on the polishing pad in a planarization operation. The planarization tool includes a controller configured to adjust a setting, of the slurry heating component, that controls a temperature of a heated slurry based on information received from the temperature sensor.

Furthermore, while described in the context of the planarization tool performing a planarization operation herein, this description equally applies to the planarization tool performing a polishing operation.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a semiconductor wafer to a polishing head in a processing chamber of a planarization tool;
dispensing, using a slurry dispense nozzle, a heated slurry onto a polishing pad in the processing chamber; and
planarizing a layer on the semiconductor wafer against the polishing pad in a planarization operation that uses a slurry mixture on the polishing pad that includes the heated slurry.

2. The method of claim 1, further comprising:
receiving, using a controller, information related to a temperature of the slurry mixture on the polishing pad; and
adjusting, using the controller, a setting that controls a temperature of the heated slurry based on the information.

3. The method of claim 2, wherein adjusting the setting that controls a temperature of the heated slurry includes:
adjusting a setting of an electro-thermal heating component of a slurry heating component that provides the heated slurry.

4. The method of claim 1, further comprising:
dispensing, using a fluid dispersion nozzle, a heated fluid proximate the slurry mixture.

5. The method of claim 4, further comprising:
receiving, using a controller, information related to a temperature of the slurry mixture on the polishing pad; and
adjusting, using the controller, a setting of a heated fluid supply system that provides the heated fluid based on the information.

6. The method of claim 5, wherein adjusting the setting of the heated fluid supply system includes:
adjusting a setting that controls a temperature of the heated fluid.

7. The method of claim 5, wherein adjusting the setting of the heated fluid supply system includes:
adjusting a setting that controls a flow rate of the heated fluid.

8. A method, comprising:
providing a semiconductor wafer to a polishing head in a processing chamber of a planarization tool;
pressing, using the polishing head, the semiconductor wafer against a polishing pad in the processing chamber to planarize a layer on the semiconductor wafer in a planarization operation;
monitoring, using a temperature sensor, a temperature of a slurry mixture on the polishing pad that is used in the planarization operation; and
adjusting, one or more settings related to the planarization operation based on information received from the temperature sensor.

9. The method of claim 8, wherein adjusting the one or more settings related to the planarization operation includes:
adjusting a setting of a slurry heating component that controls a temperature of a heated slurry dispensed through a slurry dispense nozzle onto the polishing head.

10. The method of claim 8, wherein adjusting the one or more settings related to the planarization operation includes:
adjusting a setting of a heated fluid supply system that controls a temperature of a heated fluid dispensed through a fluid dispersion nozzle proximate the slurry mixture.

11. The method of claim 8, wherein adjusting the one or more settings related to the planarization operation includes one or more of:
adjusting a setting that controls a rotational velocity of the polishing head, or
adjusting a setting that controls a compressive force that presses the semiconductor wafer against the polishing pad using the polishing head.

12. The method of claim 8, wherein adjusting the one or more settings related to the planarization operation includes:
determining at least one parameter related to adjusting the one or more settings using a machine learning model.

13. A planarization tool, comprising:
a polishing pad; and
a slurry temperature control system, comprising:
a slurry heating component; and
a temperature sensor configured to monitor a temperature of a slurry mixture on the polishing pad in a planarization operation; and
a controller configured to adjust a setting, of the slurry heating component, that controls a temperature of a heated slurry based on information received from the temperature sensor.

14. The planarization tool of claim 13, wherein the slurry heating component comprises:
an electro-thermal heating component.

15. The planarization tool of claim 14, wherein the electro-thermal heating component is part of a jacket that surrounds at least a portion of a slurry supply line connected with a slurry dispense arm of the planarization tool.

16. The planarization tool of claim 15, wherein the electro-thermal heating component is embedded in the jacket.

17. The planarization tool of claim 15, wherein the electro-thermal heating component is on the jacket.

18. The planarization tool of claim 15, wherein the jacket comprises a metal material, and wherein the slurry supply line comprises:
a polytetrafluoroethylene material.

19. The planarization tool of claim 13, wherein the setting is a first setting, the slurry temperature control system further comprises a heated fluid supply system, and the controller is further configured to adjust at least one of:
a second setting of the heated fluid supply system that controls a temperature of heated fluid based on the information, or
a third setting of the heated fluid supply system that controls a flow rate of the heated fluid based on the information,
wherein the heated fluid is dispensed proximate a slurry dispense nozzle on a slurry dispense arm of the planarization tool.

20. The planarization tool of claim 19, wherein the controller is configured to determine at least one parameter related to adjusting at least one of the first setting, the second setting, or the third setting using a machine learning model.
